(19) United States
(12) Patent Application Publication
(10) Pub. No.: US 2024/0155815 A1
(43) Pub. Date: May 9, 2024

(54) METHOD FOR APPLYING BMC ANALYTICAL LOCAL FAN CONTROL MODEL IN RUGGED ENVIRONMENT

(71) Applicant: Korea Electronics Technology Institute, Seongnam-si (KR)

(72) Inventors: Jae Hoon AN, Incheon (KR); Young Hwan KIM, Yongin-si (KR); Ki Cheol PARK, Namyangju-si (KR)

(73) Assignee: Korea Electronics Technology Institute, Seongnam-si (KR)

(21) Appl. No.: 18/387,222

(22) Filed: Nov. 6, 2023

(30) Foreign Application Priority Data
Nov. 9, 2022 (KR) 10-2022-0148300

(51) Int. Cl. H05K 7/20

(52) U.S. Cl. CPC H05K 7/20836; H05K 7/20727

(57) ABSTRACT

There is a method for applying a BMC analytical local fan control model in a rugged environment. A server chassis cooling fan control method according to an embodiment controls rotation speeds of cooling fans on a zone basis while identifying/managing a temperature distribution of an edge server chassis on a zone basis through BMC data analysis. Accordingly, a damage that may be caused by increased temperature of an edge server in a rugged environment may be minimized, and also, power consumption for cooling an edge server may be reduced.

### CROSS-REFERENCE TO RELATED APPLICATION(S) AND CLAIM OF PRIORITY

This application is based on and claims priority under 35 U.S.C. § 119 to Korean Patent Application No. 10-2022-0148300, filed on Nov. 9, 2022, in the Korean Intellectual Property Office, the disclosure of which is herein incorporated by reference in its entirety.

### BACKGROUND

### Field

The disclosure relates to an edge server chassis control technology, and more particularly, to a method for controlling a rotation speed of a cooling fan of an edge server chassis by analyzing baseboard management controller (BMC) data in a rugged environment.

### Description of Related Art

In a rugged environment in which external temperature is 63° C. or higher or −21° C. or lower, information technology (IT) equipment is difficult to operate normally and hence management thereon is more highlighted. However, current technologies for overcoming such a rugged environment focus on only a hardware-level approach for reinforcing/supplementing an exterior of IT equipment.

However, only the above-described approach does not well cope with abnormal climate which becomes more serous in recent years. In addition, a rugged environment caused by humidity or dusts may be conceived. Accordingly, there is a need for a solution for coping with a rugged environment from different points of view.

Occurrence of a breakdown in an edge server in a rugged environment may result in a loss of control for the edge server which should provide service. In the case of a rugged environment of ultra-high temperature, it is important to cool an edge server through control of a fan.

However, power consumed in a cooling fan almost reaches 10% of the whole power of an edge server, and hence there is a need for a solution for reducing power consumption of a cooling fan, and this solution should be achieved on the premise that cooling efficiency of an edge server is not degraded.

### SUMMARY

The disclosure has been developed in order to solve the above-described problems, and an object of the disclosure is to provide a method for controlling a rotation speed of a cooling fan of an edge server chassis on a zone basis through BMC data analysis, as a solution for reducing power consumption required for cooling an edge server while minimizing a damage caused by increased temperature of the edge server in a rugged environment.

According to an embodiment of the disclosure to achieve the above-described object, a server chassis cooling fan control method may include: a step of generating a chassis temperature distribution map for respective zones of a chassis in which servers are mounted; and a step of controlling cooling fans installed in the respective zones based on the generated chassis temperature distribution map.

The chassis temperature distribution map may be a map that represents a temperature distribution for the respective zones that are obtained by partitioning the chassis vertically and horizontally.

The step of generating the chassis temperature distribution map may include: a step of generating the chassis temperature distribution map based on data related to a position and a temperature of each edge server; and a first calibration step of calibrating the generated chassis temperature distribution map, based on a future workload that is predicted for each edge server.

The first calibration step may include calibrating for only zones in which a temperature change rate is greater than or equal to a reference value.

The server chassis cooling fan control method according to the disclosure may further include a second calibration step of calibrating a temperature of each zone of the chassis temperature distribution map according to a centrality of each zone.

The second calibration step may be performed only when an average temperature of the chassis temperature distribution map exceeds a reference temperature.

The step of controlling may include: a step of calculating rotation speeds of cooling fans installed in the respective zones, based on the generated chassis temperature distribution map; and a third calibration step of calibrating calculated rotation speeds for cooling fans which are operated in excess of a threshold driving time.

The server chassis cooling fan control method according to the disclosure may further include a fourth calibration step of calibrating calculated rotation speeds when an air quality level is greater than or equal to a threshold level.

The server chassis cooling fan control method according to the disclosure may further include a fifth calibration step of calibrating calculated rotation speeds based on a distribution of rotation speeds of the cooling fans.

According to another aspect of the disclosure, there is provided a server chassis control system including: cooling fans which are installed in a server chassis; and a chassis management module configured to generate a chassis temperature distribution map for respective zones of a chassis in which servers are mounted, and to control cooling fans installed in respective zones based on the generated chassis temperature distribution map.

According to still another aspect of the disclosure, there is provided a server chassis cooling fan control method including: a step of generating a chassis temperature distribution map for respective zones of a chassis in which servers are mounted; and a step of calculating rotation speeds of cooling fans which are installed in respective zones, based on the generated chassis temperature distribution map.

According to yet another aspect of the disclosure, there is provided a computer-readable recording medium having a program recorded thereon to perform a server chassis cooling fan control method, the method including: a step of generating a chassis temperature distribution map for respective zones of a chassis in which servers are mounted; and a step of calculating rotation speeds of cooling fans which are installed in respective zones, based on the generated chassis temperature distribution map.

According to embodiments of the disclosure as described above, by controlling rotation speeds of cooling fans on a zone basis while identifying/managing a temperature distribution of an edge server chassis on a zone basis through BMC data analysis, a damage that may be caused by increased temperature of an edge server in a rugged environment may be minimized, and also, power consumption for cooling an edge server may be reduced.

Other aspects, advantages, and salient features of the invention will become apparent to those skilled in the art from the following detailed description, which, taken in conjunction with the annexed drawings, discloses exemplary embodiments of the invention.

Before undertaking the DETAILED DESCRIPTION OF THE INVENTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 is a view illustrating a server chassis structure to which an embodiment of the disclosure is applicable;

FIG. 2 is a view illustrating cooling fans which are installed on a rear surface of an edge server chassis;

FIG. 3 is a view illustrating a concept of BMC analytical cooling fan control by a chassis manager module;

FIG. 4 is a view illustrating an example of a cooling fan monitoring screen;

FIG. 5 is a flowchart provided to explain a chassis cooling fan control method according to another embodiment of the disclosure;

FIG. 6 is a view illustrating an example of a chassis temperature distribution map; and

FIG. 7 is a view to explain an additional control method at a cooling fan rotation speed step; and

FIG. 8 is a view to explain an additional control method at a cooling fan rotation speed step.

### DETAILED DESCRIPTION

Hereinafter, the disclosure will be described in more detail with reference to the accompanying drawings.

Embodiments of the disclosure propose a cooling fan control method of a BMC data analytical edge server chassis in a rugged environment. The disclosure relates to a technology for controlling a rotation speed of a cooling fan on a zone basis while identifying/managing a temperature distribution of an edge server chassis on a zone basis through BMC data analysis.

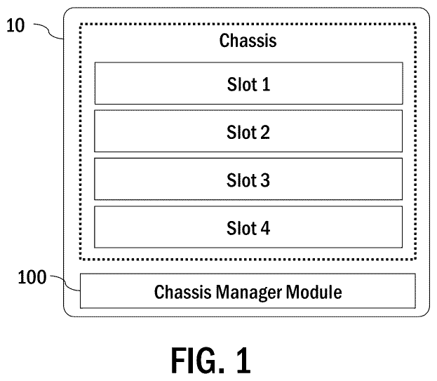

FIG. 1 is a view illustrating an edge server chassis structure to which an embodiment of the disclosure is applicable. As shown in FIG. 1, an edge server chassis 10 may include a plurality of slots to accommodate a plurality of edge servers, and may include a chassis manager module 100 to manage/control the chassis.

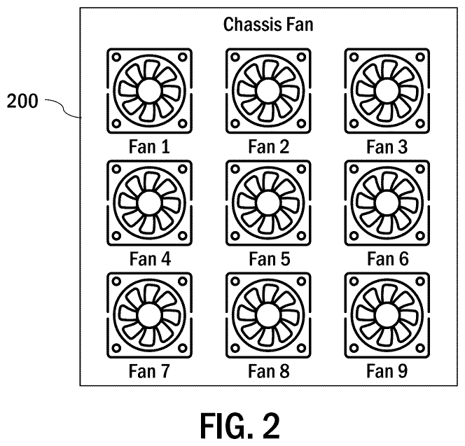

One of the main functions of the chassis manager module 100 is controlling cooling fans 200 which are installed on a rear surface of the edge server chassis 10 as shown in FIG. 2. The cooling fans 200 may reduce temperature of edge servers mounted in the edge server chassis 10, thereby preventing a damage to edge servers caused by increased temperature of edge servers in a rugged environment.

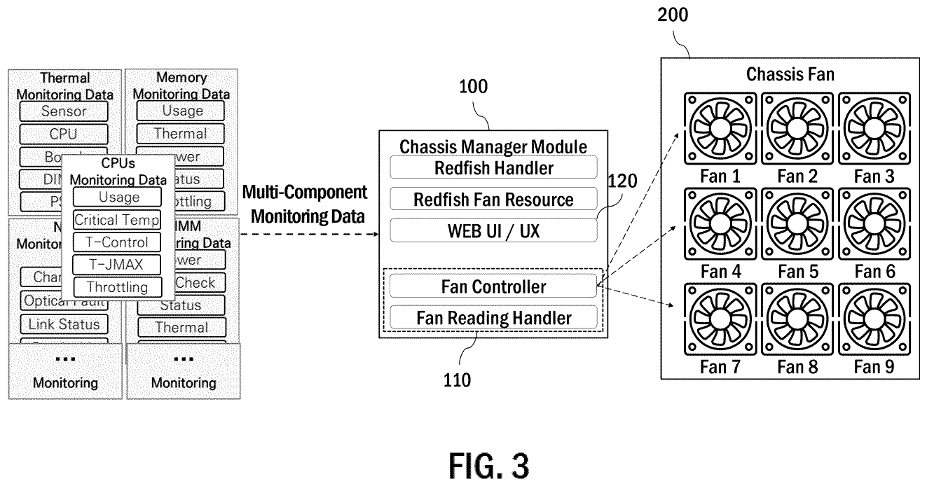

FIG. 3 is a view illustrating a concept of cooling fan control by the chassis manager module 100. As shown in FIG. 3, the chassis manager module 100 may collect state monitoring data regarding each edge server from a baseboard management controller (BMC) of each edge server.

A cooling fan controller 110 of the chassis manager module 100 may analyze the collected BMC data and may individually control the cooling fans 200. That is, the cooling fans 200 are operated at different rotation speeds by the cooling fan controller 110.

The above operation reflects that temperature locally varies in the edge server chassis 10, and not only effective heat dissipation but also reduction of power consumption caused by driving of cooling fans may be achieved through individual fan control.

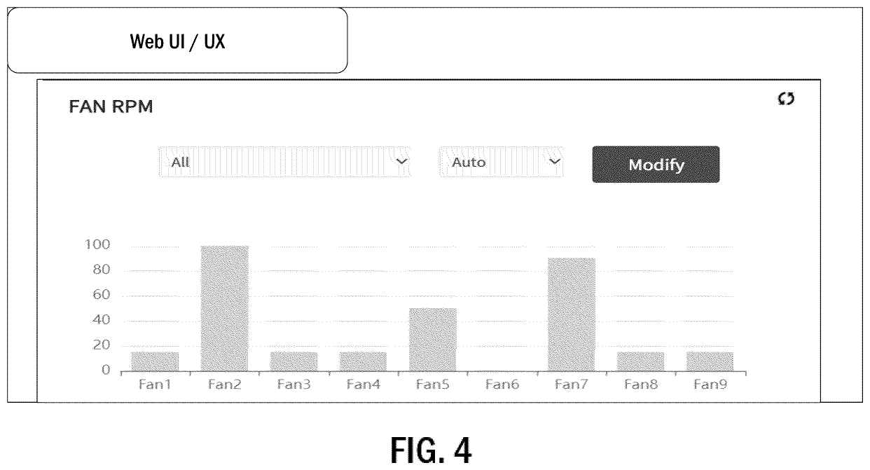

A WEB UI/UX module 120 may generate a cooling fan monitoring screen under control of the cooling fan controller 110 and may provide the cooling fan monitoring screen to an edge server manager. The cooling fan monitoring screen provided is illustrated in FIG. 4. As shown in FIG. 4, the cooling fan monitoring screen shows a cooling fan rotation speed of each cooling fan.

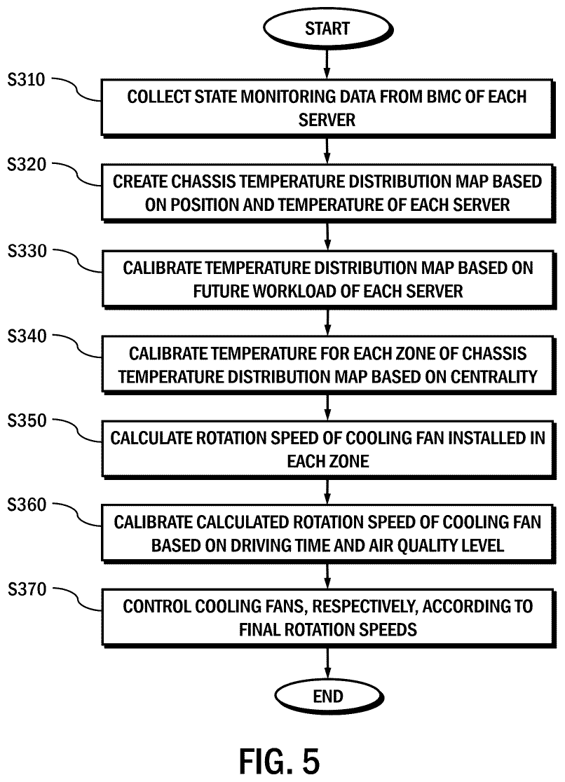

A local/individual fan control method by the cooling fan controller 110 will be described hereinbelow in detail with reference to FIG. 5. FIG. 5 is a flowchart provided to explain a chassis cooling fan control method according to another embodiment.

As shown in FIG. 5, the cooling fan controller 110 may collect state monitoring data regarding each edge server from a BMC of each edge server (S310). At step S310, state monitoring data of edge server #1 mounted in slot #1 may be provided by a BMC of edge server #1, state monitoring data of edge server #2 mounted in slot #2 may be provided by a BMC of edge server #2, . . . , and state monitoring data of edge server #n mounted in slot #n may be provided by a BMC of edge server #n.

The state monitoring data may include 1) temperature data of an edge server, and 2) resource usage data.

The cooling fan controller 110 may create a chassis temperature distribution map for each zone of the chassis, based on position and temperature data of each edge server collected at step S310 (S320). The “chassis temperature distribution map for each zone of the chassis” (hereinafter, referred to as a “chassis temperature distribution map”) is a map representing a temperature distribution of each zone that is obtained by partitioning the chassis vertically and horizontally.

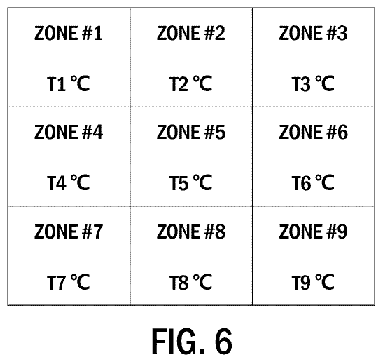

The chassis temperature distribution map is illustrated in FIG. 6. A temperature of each zone in the chassis temperature distribution map may be calculated by applying a weighting according to an occupancy rate to a temperature value of each edge server positioned in each zone, and adding up weighted values. For example, when edge server #1 occupies zone #1 by 70% and edge server #2 occupies zone #1 by 30%, a temperature of zone #1 is calculated by expression of “0.7*(temperature of edge server #1)+0.3*(temperature of edge server #2).

Thereafter, the cooling fan controller 110 may calibrate the chassis temperature distribution map created at step S320, based on a future workload predicted for each edge server (S330). The future workload may be calculated through an algorithm that may predict a future workload based on a current resource usage change of an edge server.

Calibrating at step S330 may not be performed for all zones constituting the chassis temperature distribution map, and may be performed only for zones where a recent temperature change rate is greater than or equal to a reference value. This is to support a pre-action in response to a frequent temperature change.

The cooling fan controller 110 may calibrate a temperature based on a centrality of each zone constituting the chassis temperature distribution map (S340). Herein, the centrality refers to how far a zone is positioned from the center of the chassis. A zone that is closer to the center of the chassis has a higher centrality index, and a zone that is further apart from the center of the chassis has a lower centrality index.

For example, when the temperature distribution map has a lattice shape of 5×5, a zone at (3, 3) has the highest centrality index, and a zone at (1, 1), a zone (1, 5), a zone at (5, 1), a zone at (5, 5) have the lowest centrality index.

However, temperature calibration at step S340 may be applied only when an average temperature of the chassis temperature distribution map, that is, an average of temperatures of zones constituting the chassis temperature distribution map, exceeds a reference temperature. This considers that, when temperature of zones is normally high, heat tends to be concentrated on the center.

Thereafter, the cooling fan controller 110 may calculate a rotation speed of a cooling fan installed in each zone, which is in charge of each zone, based on the chassis temperature distribution map completed through steps S320 to S340 (S350).

The cooling fan controller 110 may calibrate the calculated rotation speed of each cooling fan, based on a driving time of each fan and current air quality (S360).

Specifically, for a cooling fan that is operated in access of a threshold driving time, a rotation speed may be slower than a target speed. For this cooling fan, the cooling fan controller 110 may calibrate a calculated rotation speed by increasing by 10%.

Even when an air quality level is greater than or equal to a threshold level, a rotation speed of a cooling fan may be slower than a target speed. This situation may occur in a rugged environment with heavy dust. In this case, the cooling fan controller 110 may calibrate by increasing rotation speeds of cooling fans.

Thereafter, the cooling fan controller 110 may control the cooling fans, respectively, according to final rotation speeds determined at step S360.

Up to now, a method for controlling cooling fans on a zone basis through BMC analysis in a rugged environment has been described with reference to preferred embodiments.

In the above-described embodiments, by controlling rotation speeds of cooling fans on a zone basis while identifying/managing a temperature distribution of an edge server chassis on a zone basis through BMC data analysis, a damage that may be caused by increased temperature of an edge server in a rugged environment may be minimized, and also, power consumption for cooling an edge server may be reduced.

When the cooling fan control method according to embodiments is applied to a rugged environment, cooling fans may be frequently operated at a rotation speed of a maximum level. This is not preferable in terms of power saving.

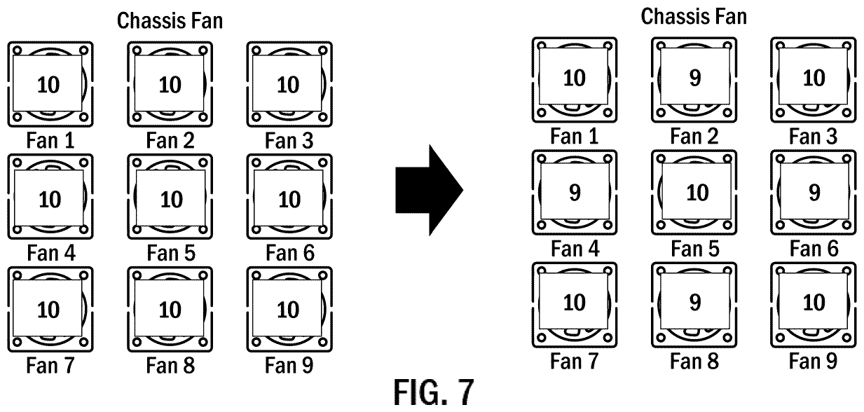

Accordingly, when the rotation speeds of all of the cooling fans are set to a maximum level of 10 as shown on the left of FIG. 7, rotation speeds of some of the cooling fans may be changed to level 9 which is lower than the maximum level by one level as shown in the right of FIG. 7. A cooling fan may have a reduced rotation speed when its neighboring cooling fans positioned over and under it and on the right and left thereof are set to the maximum level of 10. This considers that overall cooling efficiency in a dense region is not greatly changed even if speed of some cooling fans is slightly reduced.

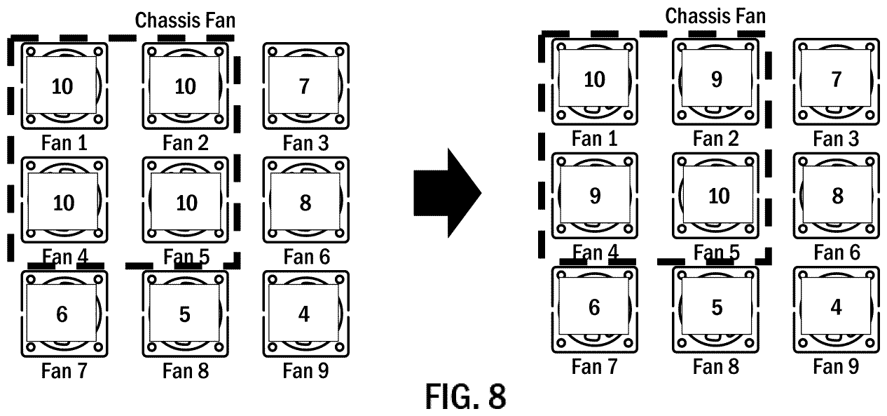

The additional control performed in this way may be applied when all cooling fans of an edge server chassis are not set to the maximum level of rotation speed and cooling fans in some local regions are set to the maximum level of rotation speed as shown in FIG. 8.

The technical concept of the present disclosure may be applied to a computer-readable recording medium which records a computer program for performing the functions of the apparatus and the method according to the present embodiments. In addition, the technical idea according to various embodiments of the present disclosure may be implemented in the form of a computer readable code recorded on the computer-readable recording medium. The computer-readable recording medium may be any data storage device that can be read by a computer and can store data. For example, the computer-readable recording medium may be a read only memory (ROM), a random access memory (RAM), a CD-ROM, a magnetic tape, a floppy disk, an optical disk, a hard disk drive, or the like. A computer readable code or program that is stored in the computer readable recording medium may be transmitted via a network connected between computers.

In addition, while preferred embodiments of the present disclosure have been illustrated and described, the present disclosure is not limited to the above-described specific embodiments. Various changes can be made by a person skilled in the at without departing from the scope of the present disclosure claimed in claims, and also, changed embodiments should not be understood as being separate from the technical idea or prospect of the present disclosure.

What is claimed is:

1. A server chassis cooling fan control method comprising:
a step of generating a chassis temperature distribution map for respective zones of a chassis in which servers are mounted; and
a step of controlling cooling fans installed in the respective zones based on the generated chassis temperature distribution map.

2. The server chassis cooling fan control method of claim 1, wherein the chassis temperature distribution map is a map that represents a temperature distribution for the respective zones that are obtained by partitioning the chassis vertically and horizontally.

3. The server chassis cooling fan control method of claim 2, wherein the step of generating the chassis temperature distribution map comprises:
a step of generating the chassis temperature distribution map based on data related to a position and a temperature of each edge server; and
a first calibration step of calibrating the generated chassis temperature distribution map, based on a future workload that is predicted for each edge server.

4. The server chassis cooling fan control method of claim 3, wherein the first calibration step comprises calibrating for only zones in which a temperature change rate is greater than or equal to a reference value.

5. The server chassis cooling fan control method of claim 3, further comprising a second calibration step of calibrating a temperature of each zone of the chassis temperature distribution map according to a centrality of each zone.

6. The server chassis cooling fan control method of claim 5, wherein the second calibration step is performed only when an average temperature of the chassis temperature distribution map exceeds a reference temperature.

7. The server chassis cooling fan control method of claim 1, wherein the step of controlling comprises:
a step of calculating rotation speeds of cooling fans installed in the respective zones, based on the generated chassis temperature distribution map; and
a third calibration step of calibrating calculated rotation speeds for cooling fans which are operated in excess of a threshold driving time.

8. The server chassis cooling fan control method of claim 7, further comprising a fourth calibration step of calibrating calculated rotation speeds when an air quality level is greater than or equal to a threshold level.

9. The server chassis cooling fan control method of claim 1, further comprising a fifth calibration step of calibrating calculated rotation speeds based on a distribution of rotation speeds of the cooling fans.

10. A server chassis control system comprising:
cooling fans which are installed in a server chassis; and
a chassis management module configured to generate a chassis temperature distribution map for respective zones of a chassis in which servers are mounted, and to control cooling fans installed in respective zones based on the generated chassis temperature distribution map.

11. A server chassis cooling fan control method comprising:
a step of generating a chassis temperature distribution map for respective zones of a chassis in which servers are mounted; and
a step of calculating rotation speeds of cooling fans which are installed in respective zones, based on the generated chassis temperature distribution map.
